(19) United States
(12) Patent Application Publication
(10) Pub. No.: US 2025/0278026 A1
(43) Pub. Date: Sep. 4, 2025

(54) STOCHASTIC-AWARE SOURCE MASK OPTIMIZATION BASED ON EDGE PLACEMENT PROBABILITY DISTRIBUTION

(71) Applicant: ASML NETHERLANDS B.V., Veldhoven (NL)

(72) Inventors: Xin LEI, San Jose, CA (US); Chenxi LIN, Newark, CA (US); Duan-Fu Stephen HSU, Fremont, CA (US)

(73) Assignee: ASML NETHERLANDS B.V., Veldhoven (NL)

(21) Appl. No.: 18/858,737

(22) PCT Filed: Jul. 7, 2023
(86) PCT No.: PCT/EP2023/068947

§ 371 Date: Oct. 21, 2024

Related U.S. Application Data
(60) Provisional application No. 63/388,353, filed on Jul. 12, 2022.

(51) Int. Cl. G03F 7/00

(52) U.S. Cl. CPC G03F 7/70283; G03F 7/705

(57) ABSTRACT

A method for stochastic-aware source mask optimization is described. A probability distribution for edge placement which accounts for stochasticity is determined. Based on the probability distribution, the source configuration, mask configuration, or the combination thereof can be optimized for a lithography process. The probability distribution for edge placement can account for a distribution of stochastic effect on edge placement, including a stochastic edge placement error contribution. The probability distribution of edge placement can be compared to a profile to determine a simulated distribution of edge placement error. A cost function, which accounts for the probability distribution of edge placement, can be used to optimize the source configuration, the mask configuration, of the combination thereof.

### CROSS-REFERENCE TO RELATED APPLICATIONS

This application claims priority of U.S. application 63/388,353 which was filed on Jul. 12, 2022 and which is incorporated herein in its entirety by reference.

The description herein relates to a method and system for optimizing a lithography process based on an edge placement probability distribution.

### BACKGROUND

A lithographic projection apparatus can be used, for example, in the manufacture of integrated circuits (ICs). A patterning der ice (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive a material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), and the reduction ratio can be different in x and y direction features the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as printing, resist coating and a soft bake. After exposure, the substrate may be subjected to other procedures (“post-exposure procedures”), such as a post-exposure bake (PER), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish die individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the deices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electromechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 am illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus. CD is the “crucial dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning deices, optical proximity correction (OPC, sometimes also referred to as “optical and process correction”) in the design layout, or other methods generally defined as “resolution enhancement techniques” (RUT.

According to an embodiment, there is provided a method for determining a source and mask configuration for a lithography process. The method comprises obtaining a source configuration, a mask configuration, or a combination thereof; calculating a probability distribution of edge placement error for a lithographic process based on the source configuration, the mask configuration, or the combination thereof; and adjusting the source configuration, the mask configuration, or the combination thereof based on the probability distribution.

In an embodiment, the edge placement error comprises a simulated edge placement error.

In an embodiment, the edge placement error is obtained from a model calibrated based on a measured edge placement error.

In an embodiment, the probability distribution corresponds to a stochastic probability distribution.

In an embodiment, the probability distribution is calibrated based on a measured probability distribution.

In an embodiment the probability distribution comprises a cumulative probability function.

In an embodiment, further comprising calculating an offset function between the probability distribution and a reference probability distribution, and wherein the adjusting is based on the offset function.

In an embodiment, the offset function between the probability distribution and the reference probability distribution is an Lp norm.

In an embodiment, the adjusting comprises adjusting the source configuration, the mask configuration, or the combination thereof until a difference between the probability distribution and a reference probability distribution is within a threshold range.

In an embodiment, the adjusting comprises adjusting the source configuration, the mask configuration, or the combination thereof based on a summation of the probability distribution in at least two of the plurality of planes.

In an embodiment, the one or more imaging performance metrics comprise at least one of a critical dimension (CD), a critical dimension uniformity (CDU), a local critical dimension uniformity (LCDU), a line edge roughness (LER), a line width roughness (LWR), a resist contour characteristic, a maximum defect size, an exposure latitude, a pattern placement error, a mask error enhancement factor, a focus, a depth of focus (DOI), a DOF latitude, a critical dimension depth of focus, a process window, a process window latitude, a common process window, a common process window latitude, an image contrast, an image log slope (ILS), a normalized image log-slope (NILS), a usable process window above a specific NILS threshold (nDOF), mask error enhancement factor (MEEF), or a combination thereof.

In an embodiment, the one or more imaging performance metrics comprise at least one of a critical dimension (CD), a critical dimension uniformity (CDU), a local critical dimension uniformity (LCDU), a line edge roughness (LER), a line width roughness (LWR), a resist contour characteristic, a maximum defect sim, an exposure latitude, a pattern placement error, a mask error enhancement factor, a focus, a depth of focus (DOF), a DOF latitude, a critical dimension depth of focus, a process window, a process window latitude, a common process window, a common process window latitude, an image contrast, an image log slope (ILS), a normalized image log-slope (NILS), a usable process window above a specific NILS threshold (nDOF), mask error enhancement factor (MEEF), or a combination thereof.

In an embodiment, wherein the adjusting comprises: determining a multi-variable cost function for the lithographic process based on the probability distribution of edge placement error, wherein the lithographic process comprises a lithographic process corresponding to the source configuration, the mask configuration, of the combination thereof; and reconfiguring one or more characteristics of the lithographic process until a termination criterion is satisfied.

According to another embodiment, there is provided a method determining, by a computer system, a multi-variable cost function of a plurality of design variables that represent characteristics of a lithographic process, wherein the multi-variable cost function is correlated with a probability distribution of edge placement, wherein the probability distribution of edge placement accounts for stochasticity of edge placement; and reconfiguring, by the computer system, one or more characteristics of the lithographic process by adjusting one or more of the plurality of design variables until a termination criteria is satisfied.

In an embodiment, the probability distribution of edge placement comprises a contribution from a stochastic edge placement distribution and a deterministic edge placement distribution.

In an embodiment, further comprising calculating a distance between the probability distribution of edge placement and a reference distribution of edge placement, and wherein the reconfiguring is based on the distance.

In an embodiment, the determining comprises: determining, by the computer system, a first multi-variable cost function of a plurality of design variables that represent characteristics of the lithographic process, wherein the first multi-variable cost function is correlated with edge placement; and reconfiguring, by the computer system, one or more characteristics of the lithographic process by adjusting one or more of the plurality of design variables until a first termination criteria is satisfied.

In an embodiment, wherein the stochastic probability distribution of edge placement comprises a stochastic probability distribution of edge placement error.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 illustrates an exemplary method for stochastic-aware source mask optimization based on an edge placement probability distribution, according to an embodiment.

FIG. 4 illustrates an exemplary method for stochastic-aware source mask optimization based on a stochastic edge placement probability distribution, according to an embodiment.

FIG. 5, depicts a schematic overview of stochastic-aware optimization for a lithography process, according to an embodiment.

FIG. 6 depicts a graphical representation of edge placement distributions, according to an embodiment.

FIGS. 7A-7B depict example distance functions for an Lp norm, according to an embodiment.

FIGS. 8A-8B depict example distance functions for an Lp norm, according to an embodiment.

FIG. 9 is a block diagram of an example computer system, according to an embodiment.

FIG. 10 is a schematic diagram of a lithographic projection apparatus, according to an embodiment.

FIG. 11 is a schematic diagram of another lithographic projection apparatus, according to an embodiment.

FIG. 12 is a detailed view of the lithographic projection apparatus, according to an embodiment.

FIG. 13 is a detailed view of the source collector module of the lithographic projection apparatus, according to an embodiment.

### DETAILED DESCRIPTION

The present disclosure describes use of a probability distribution of edge placement to optimize a source configuration, a mask configuration, or a combination thereof for a lithography process. The probability distribution of edge placement can account for stochastic effects in edge placement, such as which give rise to stochastic edge placement errors (SEPE). Stochasticity may be a function of a physical property of the lithography process and difficult to remove at lithographic wavelengths. A probability distribution of stochastic edge placement can be determined and convolved with a distribution of edge placement to generate a probability distribution of edge placement which accounts for stochasticity.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm. In the present document, the term “radiation source” or “source” is used to encompass all types of sources of radiation, including laser souses incandescent sources, etc. which may include treatment of the radiation between the radiation source and the target or other parts of the optics, including filtering, collimating, focusing, etc.

A patterning device can comprise, or can form, one or more design layouts. The design layout can be generated utilizing CAD (computer-aided design) programs. This process is often referred to as EDA (electronic design automation). Most CAD programs follow a set of predetermined design rules in order to create functional design layouts/patterning devices. These rules are set based processing and design limitations. For example, design rules define the space tolerance between devices (such as gates, capacitors, etc.) or interconnect lines, to ensure that the devices or lines do not interact with one another in an undesirable way. One or more of the design rule limitations may be referred to as a “critical dimension” (CD). A critical dimension of a device can be defined as the smallest width of a line or hole, or the smallest space between two lines or two holes. Thus, the CD regulates the overall size and density of the designer device. One of the goals in device fabrication is to faithfully reproduce the original design intent on the substrate (via the patterning device).

The tots “mask” or “patterning device” as employed in this text may be broadly interpreted as referring to a generic patterning device that can be used to endow an incoming radiation bean with a patterned cross-section, corresponding to a pattern that is to be created in a target portion of the substrate. The term “light valve” can also be used in this context. Besides the classic mask (transmissive or reflective: binary, phase-shifting, hybrid, etc.), examples of other such patterning devices include a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. Examples of other such patterning devices also include a programmable LCD array. An example of such a construction is given in U.S. Pat. No. 5,229,872, which is incorporated herein by reference.

The term “projection optics” as used herein should be broadly interpreted as encompassing various types of optical systems, including refractive optics, reflective a optics, apertures and catadioptric optics, for example. The term “projection optics” may also include components operating according toy of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

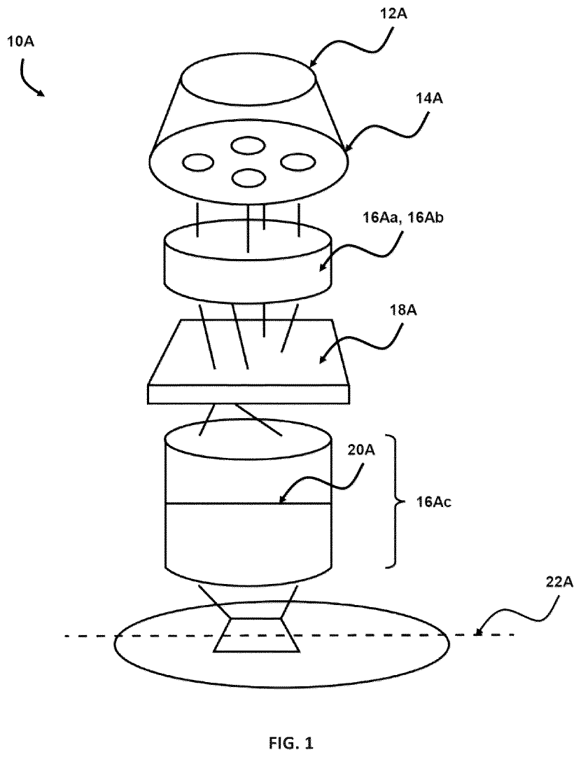

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (the lithographic projection apparatus itself need not have the radiation source), illumination optics which, e.g., define the partial coherence (denoted as sigma) and which may include optics 14A, 16Aa and 16Ab that shape radiation from the source 12A; a patterning device (or mask) 18A; and transmission optics 16Ac that project an image of the patterning device pattern onto a substrate plane 22A.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e., radiation) to a patterning device and projection optics direct and shape the illumination, via is the patterning device, onto a substrate. This is not to disclaim that the source does not itself provide patterning, directing, or shaping to the radiation or that patterning, directing, or shaping does not occur between the source and the projection optics. The projection optics may include at least some of the components 14A, 16Aa. 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEW) and development). Optical properties of the lithographic projection apparatus (e.g., properties of the illumination, the patterning do ice and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0150251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1,1] or other appropriate ranges).

The thin-mask approximation, also called the Kirchhoff boundary condition, is widely used to simplify the determination of the interaction of the radiation and the patterning deuce. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “β(3D”) may become significant. Encompassing this scattering in the mask transmission function may enable the mask: transmission function to better capture the interaction of the radiation with the patterning device. A mask transmission function under the thin-mask approximation may be referred to as a thin-mask transmission function. A mask; transmission function encompassing M3D may be referred to as a M3D mask transmission function.

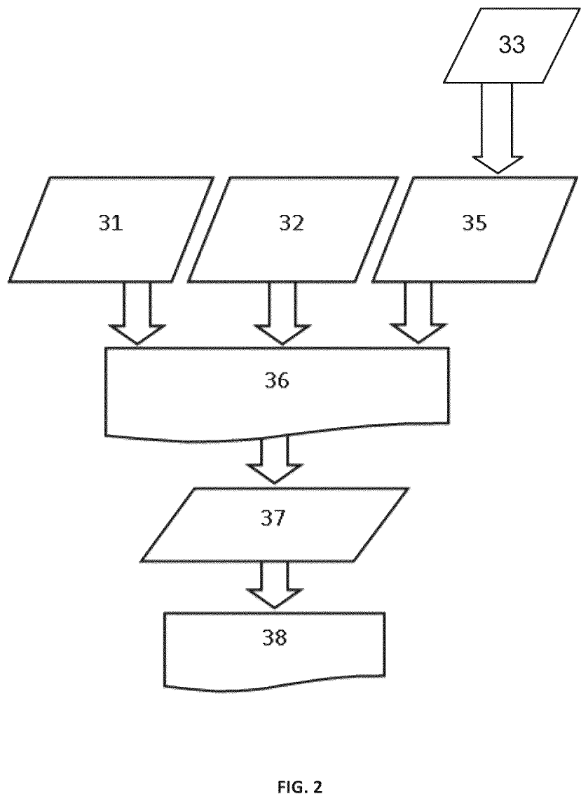

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, source model 31 can represent the optical characteristics of the source that include, but are not limited to, numerical aperture settings, illumination sigma ta) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or another rile format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e., circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either b) experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as Equation 1, below:

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, pattern placement error, image distortion, image rotation, stochastic variation, throughput, local CD variation, process window, an interlayer characteristic, or a combination thereof. In one embodiment, the design variables (z₁, zᵣ, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ (z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront IA manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil till ratio. For some illumination designs, a low pupil till ratio may discard radiation, leading to lower throughput. Throughput may also be affected by the resist chemistry. Slower resist (e.g., a resist that requires higher amount of radiation to be properly exposed) leads to lower throughput.

As used herein, the term “process model” means a model that includes one or more models that simulate a patterning process. For example, a process model can include any combination of: an optical model (e.g., that models a lens system/projection system used to deliver light in a lithography process and may include, modelling the final optical image of light that goes onto a photoresist), a resist model (e.g., that models physical effects of the mist, such as chemical effects due to the light), an optical proximity correction (OPC) model (e.g., that can be used to make masks or reticles and may include sub-resolution resist features (SRAFs), etc.).

As used herein, the term “concurrently” means that two or more things are occurring at approximately, but not necessarily exactly, at the same time. For example, varying a pupil design concurrently with a mask pattern can mean making a small modification to a pupil design, then making a small adjustment to a mask pattern, and then another modification to the pupil design, and so on. However, the present disclosure contemplates that in some parallel processing applications, concurrency can refer to operations occurring at the same time, or having some overlapping in time.

The present disclosure provides apparatuses, methods and computer program products which, among other things, relate to modifying or optimizing features of a lithography apparatus in order to increase performance and manufacturing efficiency. The features that can be modified can include an optical spectrum of light used in the lithography process, a mask, a pupil, etc. Any combination of these features (and possibly others) can be implemented in order to improve, for example, a depth of focus, a process window, a contrast, or the like, of a lithography apparatus. In some embodiments, modification of one feature affects the other features. In this way, to achieve the desired improvements, multiple features can be concurrently modified/varied, as described below.

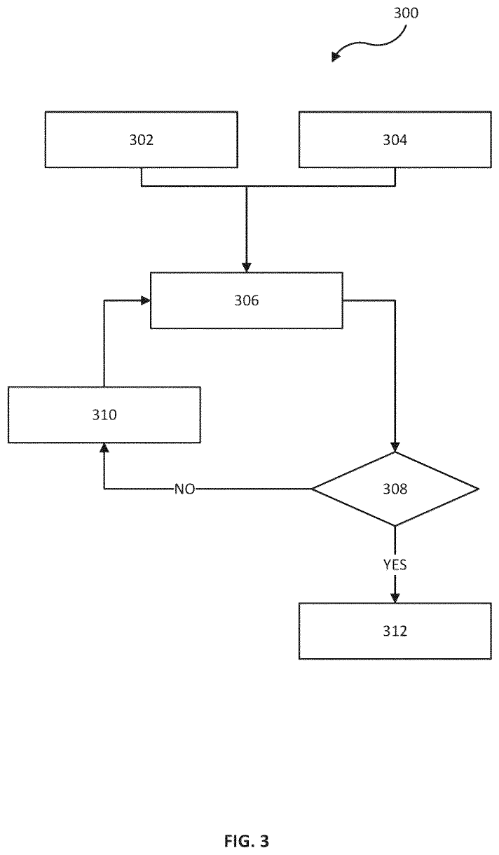

FIG. 3 illustrates an exemplary method 300 for stochastic-aware source mask optimisation based on an edge placement probability distribution, according to an embodiment. Each of these operations is described in detail below. The operations of method 300 presented below are intended to be illustrative. In some embodiments, method 300 may be accomplished with one or more additional operations not described, and/or without one or more of the operations discussed. Additionally, the order in which the operations of method 300 are illustrated in FIG. 3 and described below is not intended to be limiting. In some embodiments, one or more portions of method 300 may be implemented (e.g., by simulation, modeling, etc.) in one or more processing devices (e.g., one or more processors). The one or more processing devices may include one or more devices executing some or all of the operations of method 300 in response to instructions stored electronically on an electronic storage medium. The one or more processing devices may include one or more devices configured through hardware, firmware, and/or software to be specifically designed for execution of one or more of the operations of method 300, for example.

At an operation 302, a source configuration is obtained. The source configuration can be a configuration for a source of a lithography process. The source configuration can be obtained based on a design layout and a set of design restrictions for the lithography process, including through source optimization.

At an operation 304, a mask configuration is obtained. The mask configuration can be a configuration of a mask for the lithography process of the operation 302. The mask configuration can be obtained based on the design layout and the set of design restrictions, including through mask optimization. The source configuration and the mask configuration may can also be co-optimized for the lithography process. The source configuration and the mask configuration may be co-optimized using an unconstrained freeform source and CTM mask co-optimization. Optimization of the source configuration, the mask configuration, or the combination thereof may include optimization with sub-resolution assist features (SRAFs). The source configuration and the mask configuration may be co-optimized using a freeform source and polygon mask co-optimization. Optimization of the source configuration, the mask configuration, or the combination thereof may include optimization based on one or more model, including a Hopkins model. Optimization of the source configuration, the mask configuration, or the combination thereof may be based on a cost function. The cost function can be based on the edge placement. In some embodiments, the cost function can be based on edge placement error.

The source configuration, the mask configuration, or the combination thereof may be optimized using a cost function based on edge placement error (EPE), where EPE represents a difference between a feature edge on as fabricated and a desired feature edge (e.g., a feature edge in a design layout). EPE may be measured at multiple points on a feature and for multiple features on a layout. A cost function may determine the sum of EPE (or a norm of EPE) for a set of evaluation points, which can be chosen for features. The cost function may further include penalty terms, such as sidelobe penalty terms, mask rule check (MRC) penalty terms, etc. The cost function may be evaluated for multiple process conditions, where the process window is comprised of a set of process conditions. An example cost function is given by Equation 2:

$$s ( {v}_{src} , {v}_{mask} ) = {\sum }_{pw , eval} {w}_{pw}^{p} {w}_{eval}^{p} {\vert {EPE}_{pw , eval} \vert}^{2 p} + {p}_{sidelobe} + {p}_{slope} + {p}_{MRC} + {p}_{src} \qquad ( 2 )$$

where s represents a cost function which is a function of a source v_{src} and a mask vₘₐₛₖ. The cost function can be determined based on a sum over the process window (pw) for the evaluation points (eval). The cost function can account for the EPE using norm p, which can be 1.2, etc., where the power to which EPE is raised can be adjusted to account for different EPE regimes. For example, p=1 can be used where the cost function depends on EPE². Increases in p can be used to account for more steeply rising cost as EPE grows. The cost function can account for EPE weighted by a process window weighting w_{wp} and an e-valuation point weighting wₚ. The cost function can also include penalty terms, such as a sidelobe penalty p_{sidelobe}, a slope penalty pₛₗₒₚₑ, an MRC penalty p_{MRC}, a source penalty p_{src}, etc. Process window conditions can include ranges in various lithography metric, including dose, defocus, mask error, hare, aberration, etc. A cost function can also be used to optimize for process window latitude, such as exposure latitude (EL), normalized image log slope (NILS), depth of focus (DOF), mask error enhancement factor (MEEF), resist profile, etc. The cost function can be used to optimize the source configuration, the mask configuration or a combination thereof by minimize the EPE, such as by gradient descent or another appropriate optimisation method. The optimization of the cost function can be driven by a reduction in EPE in order to conform the printed contour to the design layout as closely as possible (or to within an acceptable threshold).

At an operation 306, a probability distribution of edge placement is determined based on at least one of the source configuration, the mask configuration, or a combination thereof and at least a stochastic component. The probability distribution of edge placement can be determined based on a resist model, a photon shot model, an optical model, an etch model, mask model, or a combination thereof. The determination of the probability distribution of edge placement can include determination based on a model of edge placement error, a model of stochastic edge placement error, or a combination thereof. The probability distribution of edge placement can include a convolution of an edge placement and a stochastic edge placement distribution.

Various lithography processes can introduce stochastic noise into the lithography process. For example, various processes (photon shot noise in optical processes, resist chemical processes, local non-uniformity in mask CD due to variations in mask writing, etc.) have a random (e.g., stochastic) component and can create stochastic effects in lithography, including in edge placement. Stochastic effects local variations in features (e.g., feature edges) and contribute to line edge roughness/line width roughness (LER/LWR) effects for linear features and local CD uniformity (LCDU) for two-dimensional (e.g., hole) features. The stochasticity of the lithography process can be characterized by metrology, where large numbers of printed features (e.g., contours) can be measured and a statistical distribution of stochasticity can be determined. From a measured statistical edge placement distribution, characteristics of the stochasticity such as mean, variance, standard deviation, symmetry, higher order moments, etc. can be calculated.

A cost function can account for EPE based on a model. Models of edge placement (e.g., lithography models) mad not account for stochasticity, but rather determine a simulated contour edge placement which is equal to a mean of the edge placement probability distribution. In some models, a stochastic component can be added to simulated stochasticity, where the stochasticity may be approximately equal to a standard deviation of the edge placement distribution. For example, Equation 3 can be used to approximate stochasticity

$$s ( {v}_{src} , {v}_{mask} ) = {\sum }_{pw , eval} {w}_{pw} ( {EPE}^{2} + {w}_{sepe} {SEPE}^{2} ) + {p}_{other} \qquad ( 3 )$$

where wₛₑₚₑ is a weighting of the stochasticity. SEPE represents the stochastic edge placement error, and pₒₜₕₑᵣ represents various penalty terms. However, adding stochasticity to EPE with a weighting term can complicate optimisation, as SEPE weighting may need to be adjusted to conform with experimental values. Further, the inclusion of SEPE may drive the optimization to nonconvergent source configurations or high EPE.

In the operation 306, a cost function which combines deterministic lithography metric such as EPE and stochastic lithographs metrics such as SEPE is used. The cost function can then be used to optimize the Lithograph) process to minimize the EPE (e.g., to maximize the agreement between a fabricated pattern and a design layout). Edge placement is represented by a probability distribution function (PDF), which may be converted to (e.g., used to calculate) a cumulative distribution function (CDF). The cumulative distribution function can be further converted to a pattern probability map or pattern probability profile (for example, in a one-dimensional case where direction perpendicular to the contour is considered). The pattern of the pattern probability map or pattern probability profile can be a resist pattern (for example, after development), can be a device pattern (for example, after etching, after deposition, etc.), or another pattern. The pattern of the pattern probability map can be a two-dimensional pattern (e.g., a pattern at or projected on a two-dimensional plane at a depth perpendicular to the lithography surface), which can be calculated for multiple different depths. The pattern of the pattern probability may can instead or additionally be a three-dimensional pattern (e.g., a pattern for a three-dimensional volume). Because edge placement depends on a nonnegligiblc stochastic contribution, edge placement may be better characterized by a probability distribution fraction which includes such a nonnegligible stochastic contribution, rather than a mean value with or without a standard deviation contribution. Edge placement may be represented by a probability distribution such as that shown in Equation 4, below:

$$s ( {v}_{src} , {v}_{mask} ) = {\sum }_{pw , eval} Distance ( {P}_{target} , {P}_{simulated} ) + {p}_{other} \qquad ( 4 )$$

where Distance(P_{target}, P_{simulated}) is a distance between a target pattern probability profile P_{target} and a simulated (e.g., modeled) pattern probability profile P_{simulated}. The pattern probability profile P_{simulated} may be equivalent to 1 minus the cumulative distribution profile of an edge placement error probability distribution (i.e., P_{EPE})

At an operation 308, it is determined if a termination criterion is reached based on the probability distribution of edge placement. The termination criterion can be a value of the cost function, a number of iterations, or another stopping criterion. The termination criterion can be a value of the distribution of edge placement, such that the distribution of edge placement is within a threshold of a target distribution. The termination criterion can be a value of a derivative of the cost function, such that it may be determined that further optimization may not improve an optimization of 3U the source configuration, the mask configuration, of the combination thereof or may not improve the optimization more than a threshold amount. V it is determined that the termination criterion is not reached, flow may continue to an operation 310 when the source configuration, the mask configuration, or a combination thereof may be adjusted based on the probability distribution of edge placement. Otherwise, flow may continue to an operation 312, where a lithography recipe may be output. At the operation 308, it may also be determined that a termination criterion is reached for which the source configuration, the mask configuration, or the combination thereof does not converge. A determination that the source configuration, the mask configuration, or the combination thereof does not converge result in output of a lithography recipe at the operation 312 where the nonconvergent lithography recipe may be indicated as nonconvergent.

At an operation 310, at least one of the source configuration, the mask configuration, or a combination thereof is adjusted based on the probability distribution of edge placement. An adjustment of the source configuration, the mask configuration, or the combination thereof may be made in a direction indicated by an offset between the simulated pattern probability profile and the target pattern probability profile. The offset may be an offset between the simulated pattern probability profile and the target pattern probability profile in one or more plane perpendicular to the lithography surface, for example at one or more depth in a resist volume or other plane parallel to the lithography surface. The offset may also be an offset in a direction not parallel to the lithography surface (e.g., perpendicular to the lithography, askew to the Lithography surface, etc.). The offset can comprise an offset determined for a three-dimensional volume, e.g., a resist volume or other three-dimensional volume describing the lithography process. The adjustment may be determined based on the cost function, including based a derivative of the cost function with respect to one or more variable of the cost function.

At an operation 312, a lithography recipe is output. The lithography recipe may comprise the source configuration, the mask configuration, or the combination thereof. The lithography recipe may comprise multiple lithography variables, including dose, process window, etc. The lithography recipe may be output to storage. The lithography recipe may be output to one or more components of the lithography process (e.g., a mask writer, a source configurer, etc.). The lithography recipe may be output as a mask configuration, as a source configuration, as a combination thereof. The lithography recipe may include predicted outcomes of the lithography process, such that the lithography process can be controlled using process control techniques. The lithography recipe may comprise a resist recipe, a mask production recipe, an etch recipe, a resist development recipe, or other constituent recipes.

As described above, method 300 (and/or the other methods and systems described herein) is configured to optimize a lithography process based on awareness of stochastic edge placement probability distribution.

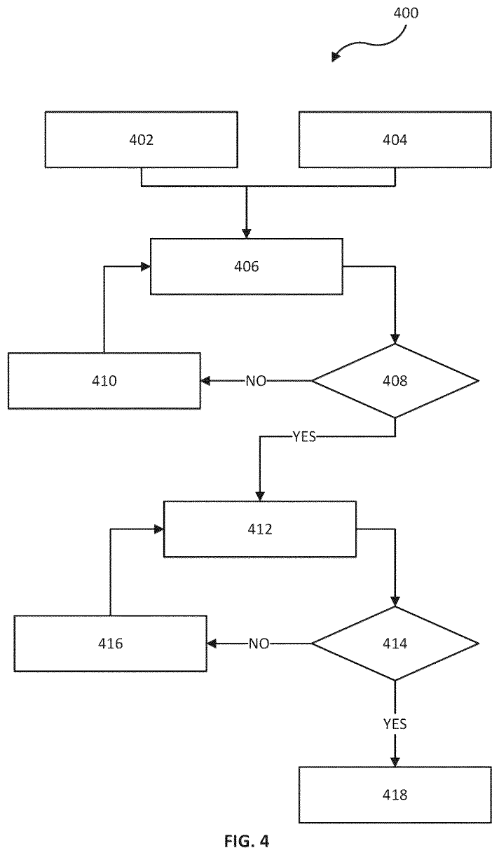

FIG. 4 illustrates an exemplary method for stochastic-aware source mask optimization based on a stochastic edge placement probability distribution, according to an embodiment. Each of these operations is described in detail below. The operations of method 400 presented below are intended to be illustrative. In some embodiments, method 400 may be accomplished with one or more additional operations not described, and/or without one or more of the operations discussed. Additionally, the order in which the operations of method 400 are illustrated in FIG. 4 and described below is not intended to be limiting. In some embodiments, one or more portions of method 400 may be implemented (e.g., by simulation, modeling, etc.) in one or more processing devices (e.g., one or more processors). The one or more processing devices may include one or more devices executing some or all of the operations of method 400 in response to instructions stored electronically on an electronic storage medium. The one or more processing devices may include one or more des ices configured through hardware, firmware, and/or software to be specifically designed for execution of one or more of the operations of method 400, for example.

At an operation 402, a source configuration is obtained. The source configuration may be obtained by any appropriate method, such as those described in reference to the operation 302 of FIG. 3.

At an operation 404, a mask configuration is obtained. The mask configuration may be obtained by any appropriate method, such as those described in reference to the operation 304 of FIG. 3.

At an operation 406, a probability distribution of edge placement is determined based on at least one of the source configuration, the mask configuration, or a combination thereof. The probability distribution of edge placement may or may not comprise a stochastic component. The probability distribution of edge placement may be determined by any appropriate method, such as those described in reference to the operation 306 of FIG. 3.

At an operation 408, it is determined if a first termination criterion is reached based on the probability distribution of edge placement. The first termination criterion may be an intermediate termination criterion. It may be determined if the first termination criterion is reached based on any appropriate method such as those described in reference to the operation 308 of FIG. 3.

If it is determined that the first termination criterion is not reached, flow may continue to an operation 410 when the source configuration, the mask configuration, or a combination thereof may be adjusted based on the probability distribution of edge placement. Otherwise, flow may continue to an operation 412, where a probability distribution of edge placement which accounts for stochasticity is determined based on at least one of the source configuration, the mask configuration, or a combination thereof.

At an operation 410, at least one of the source configuration, the mask configuration, or a combination thereof is adjusted based on the probability distribution of edge placement. At least one of the source configuration, the mass, configuration, or the combination thereof may be adjusting using any appropriate method, such as those previously described in reference to the operation 310 of FIG. 3.

At an operation 412, a probability distribution of edge placement is determined based on at least one of the source configuration, the mask configuration, or a combination thereof which accounts for stochasticity. The probability distribution which accounts for stochasticity may be determined using any appropriate method, including those described in reference to the operation 306 of FIG. 3.

At an operation 414, it is determined if a second termination criterion is reached based on the probability distribution of edge placement which accounts for stochasticity. The second termination criterion may be an ultimate termination criterion. It may be determined if the second termination criterion is reached based on any appropriate method, such as those described in reference to the operation 308 of FIG. 3. The first termination criterion and the second termination criterion may be related, where the second termination criterion may be a tighter criterion than the first termination criterion.

If it is determined that the second termination criterion is not reached, flow may continue to an operation 416 when the source configuration, the mask configuration, or a combination thereof may be adjusted based on the probability distribution of edge placement. Otherwise, flow may continue to an operation 418, a lithography recipe may be output.

At the operation 416, at least one of the source configuration, the mask configuration, or a combination thereof is adjusted based on the probability distribution of edge placement which accounts for stochasticity. An adjustment of the source configuration, the mask configuration, or the combination thereof may be made in a direction indicated by an offset between the probability distribution of edge placement which accounts for stochasticity and the target probability distribution of edge placement. The adjustment may be determined based on the cost function, including based a derivative of the cost function with respect to one or more variable of the cost function.

The adjustment of the source configuration, the mask configuration, or the combination thereof in the operation 416 may be of a different type that the adjustment of the source configuration, the mask configuration, or the combination thereof in the operation 410. For example, the adjustment in the operation 410 may correspond too freeform source and polygon mask co-optimization, while the adjustment in the operation 416 may correspond to a mask: only optimization based on a Hopkins model.

At an operation 418, a lithography recipe is output. The lithography recipe may be output using any appropriate method, including those described in reference to the operation 312 of FIG. 3.

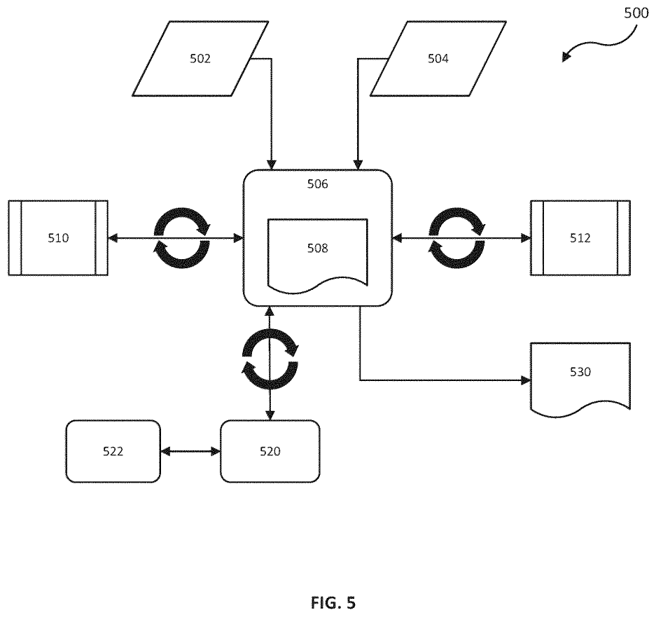

FIG. 5, depicts a schematic overview of stochastic-aware optimization for a lithography process 500. The lithography process 500 may be any type of lithography process, including UV, EUV, etc. The lithography process may be characterized by a design layout 502 and a set of requirements 504. The design layout 502 may include information about multiple layers. The design layout 502 may include information about three-dimensional shapes of features contained in the design layout 502. The set of requirements 504 may be instrumentation requirements (e.g., limitations, ranges, etc. corresponding to process equipment), material requirements (e.g., limitations, ranges, etc. imposed on a lithography process by materials of the device to be fabricated which may or may not be exposed or patterned by the current lithography process), customer requirements (e.g., limitations, ranges, etc. requested by the supplier of the design layout 302), etc. The set of requirements 504 may include a set of design rules, with which a recipe 530 for the lithography process may preferentially comply.

A process optimizer 506 may operate to optimize the lithography process 500. The design layout 502 and set of requirements 504 may be input into the process optimizer 506 or acquired by the process optimizer 506. The process optimizer 500 may optimize the recipe 530 for the lithography process 500 in order to comply with the design layout 502 and the set of requirements 504. The process optimizer 506 may also optimize process window conditions, including exposure latitude. common process window, etc., or other lithography metrics, including EPE. LCDU, etc., which may be extraneous to the design layout 502 or the set of requirements 504. The process optimizer 506 may operate based on a cost function 508.

The cost function 508 can include weighted contributions from lithography metrics, such as EPE. The cost function 508 can include contributions from multiple pattern probability profiles, including pattern probability profiles calculated for various directions perpendicular to the lithography surface, such as at various heights in a z-direction in a resist volume or other three-dimensional volume. The cost function 508 can include contributions from a sum of multiple pattern probability profiles, such as pattern probability profiles calculated for various directions perpendicular to the lithography surface, such as at various heights in a z-direction in a resist volume or other three-dimensional volume. The cost function 508 can include contributions from a three-dimensional pattern probability profile, such as a pattern probability profile calculated for a three-dimensional resist volume, three-dimensional process volume (e.g., including an etch volume, development volume. depositional volume, etc.). The cost function 508 can also include penalties for various parameters, which can be used to drive the process optimize 506 towards a recipe 530 which satisfies the design layout 502 and the set of requirements 304. The cost function 508 can be a multi-variable cost function. The cost function 508 may be a differentiable function. The cost function 508 can be used by the process optimizer 506 to optimize a recipe 530, such as by gradient descent or other methods. The cost function 508 can be determined based on an iteration of a lithography recipe, where the recipe 530 is the optimized iteration of the lithography recipe. Optimization includes determination of a recipe. source configuration, mask configuration, etc. which satisfies the design layout 502 and the set of requirements 504. Optimization is not limited to determination of the best of all possible recipes or configurations, but includes determination of recipes or configurations which fall within an allowable threshold of an ideal recipe or configuration or which otherwise satisfy the design layout 502 and the set of requirements 504. Optimization may include choosing between multiple recipes or configurations which satisfy the design layout 502 and the set of requirements SW, including choosing based on process window considerations, lithographic metric considerations, etc.

The cost function 508 can be determined based on a mask configuration, which may be determined based on a mask optimization 510. The mask optimization 510 can operate iteratively on a mask configuration, including by making changes to the mask configuration based on the cost function 508. The mask optimization 510 can include a continuous transmission mask (CTM) optimization, a polygon optimization, a Manhattanized optimization, etc. The mask optimization 510 can include generation of one or more assist features. The mask optimization 510 can interact with a lithography model, such as a resist model, a photon model, an etch model, etc. which can be used to generate a predicted output of the lithography process 500 for an iteration of the mask optimization 510.

The cost function 508 can be determined based on a source configuration, which may be determined based on a source optimization 512. The source optimization can operation iteratively on a source configuration, including by making changes to the mask configuration based on the cost function 508. The source optimization 512 can include an unconstrained freeform optimization, a freeform optimization, etc. The source optimization 512 can include optimization of one or more parameters of a spectrum of radiation. The source optimization 512 can interact with a lithography model, such as a resist model, a photon model, an etch model, etc. which can be used to generate a predicted output of the lithography process 500 for an iteration of the source optimization 512.

The process optimizer 506 can also interact with other optimization processes, including dose optimization, focus optimization, spectrum optimization, etc. The mask optimization 510 and the source optimization 512 can occur simultaneously, alternatively, on different time scales, etc. The process optimizer 506 operate to co-optimize the mask optimization 510 and the source optimization 512.

The process optimizer 506 may determine the cost function 508 based on a current iteration of the recipe of the lithography process 500. The process optimizer 506 may determine the cost function 508 based on a modeled output of the current iteration of the lithography process 500. The process optimizer 506 may determine the cost function 508 based on an output of an edge placement estimator 520. The edge placement estimator 520 may be a product of a model generated based on the current iteration of the lithography process 500. The edge placement estimator 520 may estimate a mean, median, or mode of edge placement. The edge placement estimator 520 may estimate one or more measure of dispersion of edge placement, such as a standard deviation. The edge placement estimator 520 may be informed by measured edge placement, including from devices produced by lithography recipes similar to a lithography recipe of the current iteration.

The edge placement estimator 520 may be in communication with or contain a stochastic edge placement estimator 522. The stochastic edge placement estimator 522 may be a product of a model generated based on the current iteration of the lithography process 500. The stochastic edge placement estimator 522 may be a product of multiple models which estimate stochasticity, including a chemical resist model, a photon shot model. mask CD non-uniformity model, etc. The stochastic edge placement estimator 522 may determine an edge placement stochasticity based on multiple physical models of stochasticity, including photonic stochasticity, chemical stochasticity, etc. The stochastic edge placement estimator 522 may determine a stochasticity based on a convolution of one or more estimates of constituent process stochasticity. The stochastic edge placement estimator 522 may determine a distribution of stochasticity, including a mean, a standard deviation. higher order moments, etc. The stochastic edge placement estimator 522 may estimate a stochastic edge placement error. The stochastic edge placement estimator 522 may determine an asymmetric distribution of stochasticity. The stochastic edge placement estimator 522 may be informed by measured stochastic edge placement, including from device produced by lithographic recipes similar to a lithographic recipe of the current iteration.

The cost function 509 may be determined based, at least in part, on evaluation of the edge placement of the current iteration of the lithography process 500 any may include evaluation of the stochastic edge placement of the current iteration. The cost function 508 may include stochastic effects in some iterations but not others, such as include stochastic effects when refining the cost function or for some types of optimisation. The edge placement may be compared to edge placement of the design layout 502. The difference between the edge placement of the current iteration of the lithography process 500 and the design layout 502 may be encompassed by an edge placement error. The difference between the edge placement of the current iteration of the lithography process 501 and the design layout 302 may account for stochasticity and may be encompassed by a stochastic edge placement error (SEPE). The edge placement error may measure a distance, a direction, or a combination thereof of the difference between the edge placement of the current iteration of the lithography process 500 and the design layout 502. The edge placement error ma's be measured for a number of evaluation points based on modeled output of the current iteration of the lithography process 500. The evaluation points may be selected based on the CD of the design layout 502. The SEPE may be a distribution, including an EPE distribution which accounts for stochasticity. The SEPE may be a CDF. The SEPE may instead be represented by an inverse of the CDF or I-CDF. The SEPE may be calculated as a Gaussian distribution which is cons of ed with an EPE distribution or other measure or EPE. In some other embodiments, the SEPE may be calculated as a Poisson distribution. The SEPE may be an asymmetrical distribution, such that stochasticity does not spread EPE equally in all direction.

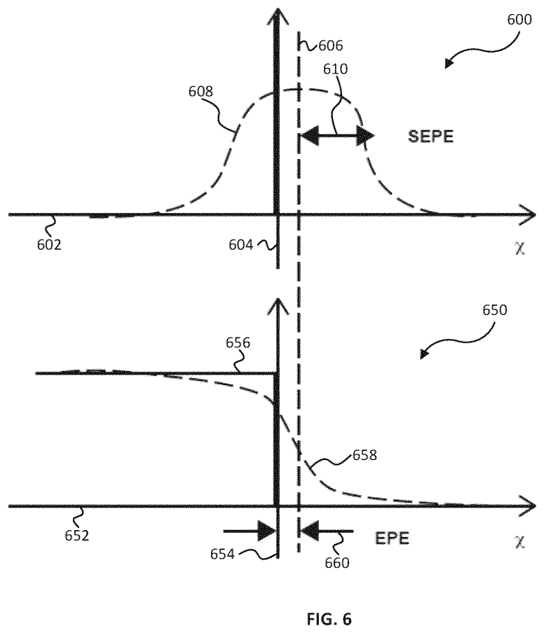

FIG. 6 depicts a graphical representation of edge placement distributions. FIG. 6 depicts a graph 600 of stochasticity of edge placement in one dimension along x-axis 602 for a set of fabricated features. The x-axis 602 can represent a direction perpendicular to a contour of a feature as-fabricated. A dotted line 608 depicts a distribution of stochastic edge placement, which corresponds to a number of fabricated features of the set of fabricated features with a given edge placement value. The number of fabricated features corresponding to an edge placement value is depicted as an intensity along y-axis 604. The distribution of stochastic edge placement, which can be SEPE when compared to a target edge placement, is depicted as Gaussian in shape. However, the distribution can comprise other shapes, including Lorentzian, Poisson, etc. The distribution of stochastic edge placement can comprise multiple contributions, for example multiple Gaussian shapes, a convolution of a Gaussian and a Poisson distribution, etc. The distribution of stochastic edge placement can be centered about an average edge placement 606 with standard deviation 610. The average edge placement can instead be a median edge placement mode of edge placement, etc. The distribution of stochastic edge placement is depicted as symmetrical, but can instead be asymmetrical. The distribution of stochastic edge placement can have different dispersion in different regions of the distribution. The distribution of stochastic edge placement can be determined based on one or more model. The distribution of stochastic edge placement can be based on measured stochasticity. The distribution of stochastic edge placement can be informed by measured stochasticity—for example the distribution of stochastic edge placement can include both modeled and measured parameters.

FIG. 6 also depicts graph 650 of a pattern probability profile along Y-axis 652 for the set of fabricated features of the graph 600. The x-axis 652 can represent the same direction perpendicular to the contour of the feature as-fabricated as represented by the x-axis 602. A dotted line 658 depicts a pattern probability profile based on the distribution of edge placement which accounts for stochasticity. The pattern probability profile average 660 corresponds to the average edge placement location of the set of fabricated features. The average can instead be another measure of central tendency, including median, weighted average, mode, etc. The number of fabricated features corresponding to a pattern probability profile value is depicted as an intensity along y-axis 654. The median pattern probability profile corresponds to the average edge placement 606, as also depicted in the graph 600. A target pattern probability profile 656 is also depicted. The distribution of EPE is given by the difference between the target pattern probability profile 656 and the simulated pattern probability profile (e.g., the pattern probability profile represented by the dotted line 658).

A probability distribution of edge placement error can be described by a relationship dependent on both EPE and SEPE, where EPE may correspond loan average EPE and SEPE may correspond to a dispersion value of EPE. The probability distribution of edge placement error can be described by an equation such as Equation 5, below:

$${P}_{EPE} = \frac{1}{SEPE \sqrt{2 π}} {e}^{- \frac{1}{2} {( \frac{x - EPE}{SEPE} )}^{2}} \qquad ( 5 )$$

for a Gaussian distribution. Other equation may be used instead.

A target profile (or distribution) can be described as a step function, such as the step function described by Equation 6, below:

$${P}_{target} = \{ \begin{matrix}1 , & x < 0 \\ 0 , & x \geq 0\end{matrix} \qquad ( 6 )$$

where the target probability distribution is a step function which is are for an x value greater than a target value and which is unity for an x value smaller than a target value. Alternatively, a target profile can be a staircase function, a linear function, etc. The target profile can be a function of the design layout, such as an ideal profile.

A simulated profile (or distribution) can be determined based on the probability distribution of EPE and SEPE. The simulation profile can be one minus the cumulative distribution function. The simulated profile can be described by Equation 7, below:

$${P}_{simulated} = \frac{1}{2} erfc ( \frac{x - EPE}{\sqrt{2} SEPE} ) \qquad ( 7 )$$

where P_{simulated} be the simulated profile. The simulated profile can be generalized as an inverse of the CDF of the probability distribution of EPE (e.g., I-CDF of P_{EPE} for a general P_{EPE}).

The lithography process can be optimized by minimizing the EPE. Minimizing EPE can be accomplished by minimizing the distance between the target profile (or P_{target}) and the simulated profile (or P_{simulated}). The distance between the profiles (or probability distributions) can be determined in a number of different ways—where different distance formulas may be more appropriate for different cost functions, different lithography models, different relationships of CD and EPE, etc. Common distance calculations involve using Lp norms, such as L1 norms, L2 norms, etc. for various p values. However, other distance calculations can be used additionally or instead.

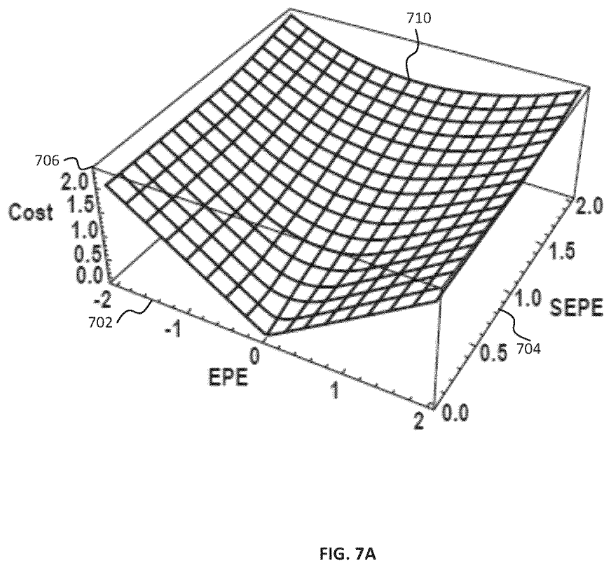

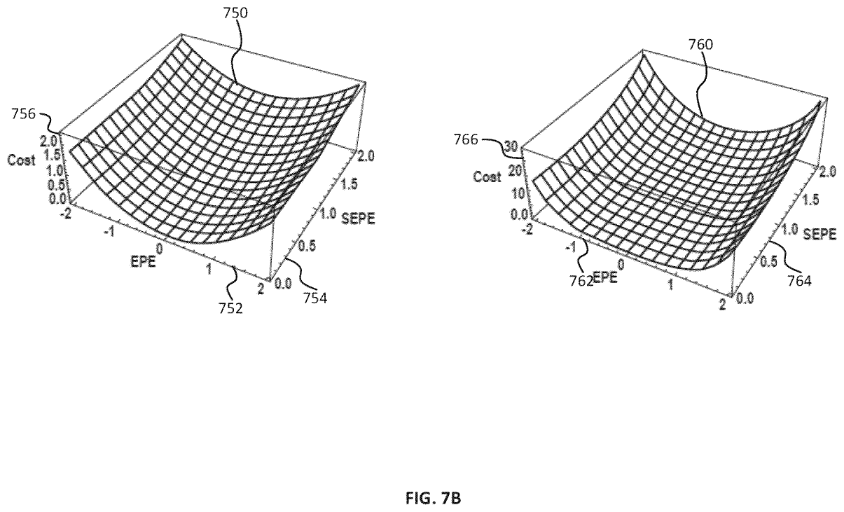

FIGS. 7A-7B depict example distance functions for an Lp norm. FIG. 7A depicts a graph 710 of an example distance function for an L1 norm. The example distance function can have a general form as given Equation 8 below:

$$Distance ( {P}_{target} , {P}_{simulated} ) = \int ( \vert {P}_{target} - {P}_{simulated} \vert ) dx \qquad ( 8 )$$

where the L1 norm is based on a sum of absolute values of distance vectors. For the specific simulated distribution function of Eq. 5, Equation 8 can be calculated more directly as Equation 9, below:

$$Distance ( {P}_{target} , {P}_{simulated} ) = {e}^{- \frac{{EPE}^{2}}{2 {SEPE}^{2}}} \sqrt{\frac{2}{π}} + \frac{1}{2} EPE erfc [ - \frac{EPE}{\sqrt{2} SEPE} ] - \frac{1}{2} EPE erfc [ \frac{EPE}{\sqrt{2} SEPE} ] \qquad ( 9 )$$

where EPE represents a determined EPE and SEPE represented a determined SEPE.

The graph 710 depicts values of the distance as a function of EPE values on axis 702. SEPE values on axis 704. The contribution of the value of the distance to a cast function is displayed on axis 706.

FIG. 7B depicts graphs 754) and 760 of an example distance function for an L1 norm for powers of p. The example distance function can have a general form as given by Equation 10, below:

$$Distance ( {P}_{target} , {P}_{si𝔪ulated} ) = {( \int ( \vert {P}_{target} - {P}_{simulated} \vert ) dx )}^{2 p} \qquad ( 10 )$$

where p can be chosen to soften the effect of distance on the cost function for distances less than unity and increase the effect of distance on the cost function for distances mote than unity. A weighting factor can also be used to adjust the value at which the cost function changes between softening the effect of distance and increasing the effect of distance. For the specific simulated distribution of Eq. 5, Equation 8 can be calculated more directly as Equation 11, below:

$$Distance ( {P}_{target} , {P}_{simulated} ) = {( {e}^{- \frac{{EPE}^{2}}{2 {SEPE}^{2}}} \sqrt{\frac{2}{π}} + \frac{1}{2} EPE erfc [ - \frac{EPE}{\sqrt{2} SEPE} ] - \frac{1}{2} EPE erfc [ \frac{EPE}{\sqrt{2} SEPE} ] )}^{2 p} \qquad ( 11 )$$

where p can be chosen to change the effect of distance on the cost function.

The graph 750 depict values of the distance for p=1 as a function of EPE values on axis 752, SEPE values on axis 754. The contribution of the value of the distance to a cost function is displayed on axis 756.

The graph 760 depict values of the distance for p=2 as a function of EPE values on axis 762. SEPE values on axis 764. The contribution of the value of the distance to a cost function is displayed on axis 766.

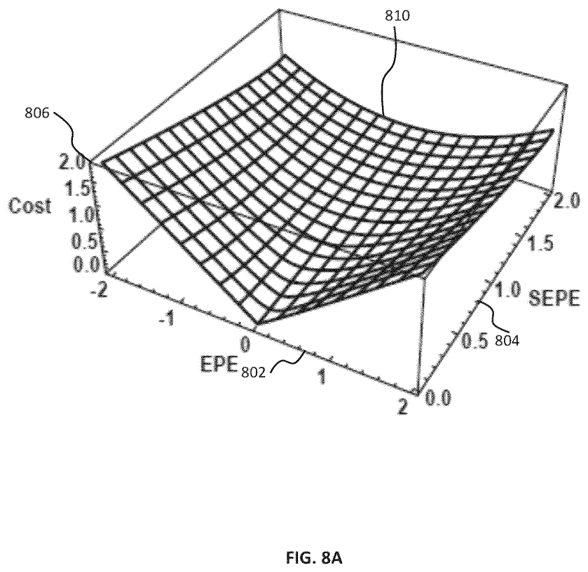

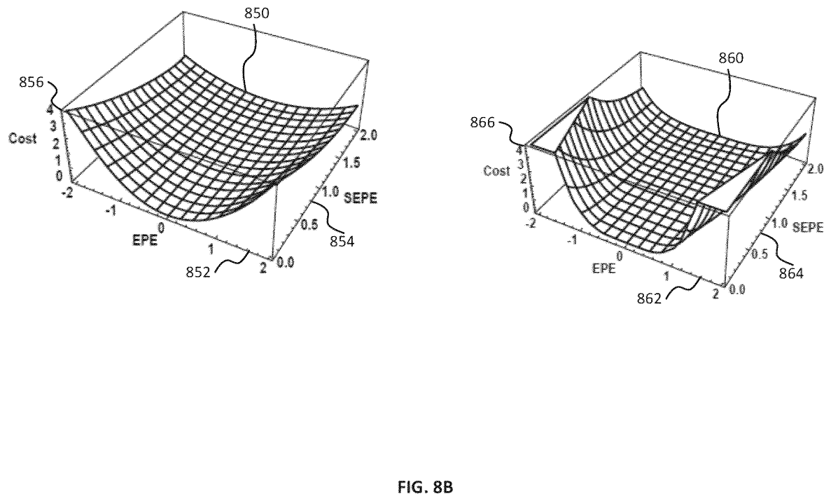

FIGS. 8A-8B depict example distance functions for an Lp norm. FIG. 8A depicts a graph 810 an example distance function for an L2 norm. The example distance function can have a general form as given by Equation 12 below:

$$Distance ( {P}_{target} , {P}_{si𝔪ulated} ) = \int {( \vert {P}_{target} - {P}_{simulated} \vert )}^{2} dx \qquad ( 12 )$$

where the L2 norm is based on a Euclidian distance. For the specific simulated distribution function of Eq. 5. Equation 12 can be calculated more directly as Equation 12, below:

$$Distance ( {P}_{target} , {P}_{simulated} ) = - \frac{SEPE erfc [ \frac{EPE}{SEPE} ]}{2 \sqrt{π}} + \frac{\begin{matrix}- 2 SEPE - 2 SEPE erf [ \frac{EPE}{SEPE} ] + \\ 2 \sqrt{2} {e}^{- \frac{{EPE}^{2}}{2 {SEPE}^{2}}} SEPE erfc [ - \frac{EPE}{\sqrt{2} SEPE} ] + EPE \sqrt{π} erfc [ \text{?}\end{matrix}}{4 \sqrt{π}} + \frac{{e}^{- \frac{{EPE}^{2}}{2 {SEPE}^{2}}} SEPE erfc [ \frac{EPE}{\sqrt{2} SEPE} ]}{2 \sqrt{π}} - \frac{1}{4} EPE {erfc [ \frac{EPE}{\sqrt{2} SEPE} ]}^{2} \qquad ( 13 )$$

$$\text{?} \text{indicates text missing or illegible when filed}$$

where EPE represents a determined EPE and SEPE represented a determined SEPE.

The graph 810 depicts values of the distance as a function of EPE values on axis 802, SEPE values on axis 804. The contribution of the value of the distance to a cost function is displayed on axis 806.

Figure SB depicts graph 850 and 864) of an example distance function for an 1.2 norm for powers of p. The example distance function can have a general form as given by Equation 14, below:

$$Distance ( {P}_{target} , {P}_{simulated} ) = {( \int {( \vert {P}_{target} - {P}_{simulated} \vert )}^{2} dx )}^{2 p} \qquad ( 14 )$$

where p can be chosen to soften the effect of distance on the cost function for distances less than unity and increase the effect of distance on the cost function for distances more than unity. A weighting factor can also be used to adjust the value at which the cost function changes between softening the effect of distance and increasing the effect of distance. For the specific simulated distribution of Eq. 5. Equation 14 can be calculated more directly as Equation 15, below:

$$Distance ( {P}_{target} , {P}_{simulated} ) = {( - \frac{SEPE erfc [ \frac{EPE}{SEPE} ]}{2 \sqrt{π}} + \frac{\begin{matrix}- 2 SEPE - 2 SEPE erf [ \frac{EPE}{SEPE} ] + \\ 2 \sqrt{2} {e}^{- \frac{{EPE}^{2}}{2 {SEPE}^{2}}} SEPE erfc [ - \frac{EPE}{\sqrt{2} SEPE} ] + EPE \sqrt{π} erfc [ \text{?}\end{matrix}}{4 \sqrt{π}} + \frac{{e}^{- \frac{{EPE}^{2}}{2 {SEPE}^{2}}} SEPE erfc [ \frac{EPE}{\sqrt{2} SEPE} ]}{2 \sqrt{π}} - \frac{1}{4} EPE {erfc [ \frac{EPE}{\sqrt{2} SEPE} ]}^{2} )}^{2 p} \qquad ( 15 )$$

$$\text{?} \text{indicates text missing or illegible when filed}$$

where p can be chosen to change the effect of distance on the cost function.

The graph 850 depict values of the distance for p=1 as a function of EPE values on axis 852, SEPE values on axis 854. The contribution of the value of the distance to a cost function is displayed on axis 856.

The graph 860 depict values of the distance for p=2 as a function of EPE values on axis 862, SEPE values on axis 864. The contribution of the value of the distance to a cost function is displayed on axis 866.

The dependence of the cost function on the distance between the target and simulated probability distribution can be chosen based on knowledge of the lithography process. Optionally, the dependence of the cost function on the distance (e.g., the norm, p value, etc.) can be selected during the optimisation process or even optimized during the optimization process. The equations shown here are provided as examples only, and other distance equations, including for other norms. can be used instead or additionally.

A tolerance may also be used for comparing edge placement to a target edge placement. A cost function may be modified so that when edge placement is determined to be the same as or to within a tolerance of the target edge placement, the portion of the cost function associated with that edge placement may be substantially zero. For a probabilistic edge placement distribution, this may mean that for values of edge placement in the probability distribution which are within a tolerance (or offset) of the target edge placement, the portion of the cost function associated with those edge placement values may be zero. For values of edge placement in the probability distribution which are outside of the tolerance, the edge placement error may be determined as a distance from the edge placement to the tolerate values of edge placement, or an EPE-offset value. The cost function may then be calculated based on the distance corresponding to the difference between edge placement and the tolerated offset.

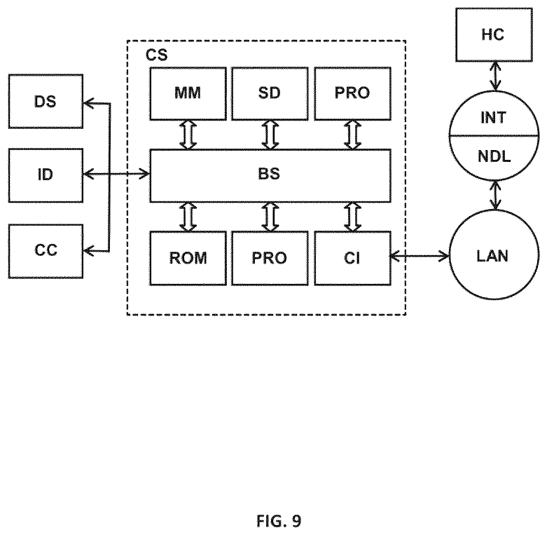

FIG. 9 is a block diagram of an example computer system CS, according to an embodiment. Computer system CS may assist in implementing the methods, flows, or the apparatus disclosed herein. Computer system CS includes a bus BS or other communication mechanism for communicating information, and a processor PRO (or multiple processors) coupled with bus BS for processing information. Computer system CS also includes a main memory MM, such as a random-access memory (RAM) or other dynamic storage device, coupled to bus BS for staring information and instructions to be executed by processor PRO. Main memory MM also may be used for storing temporary variables or other intermediate information during execution of instructions to be executed by processor PRO, for example. Computer system CS includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media. volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of hole, a RAM, a PROM, and EPROM, a FLASH-EPROM, any other memory chip or cartridge. Non-transitory computer readable media can have instructions recorded thereon. The instructions, when executed by a computer. can implement any of the features described herein. Transitory computer-readable media can include a carrier wave or other propagating electromagnetic signal.

Various forms of computer readable media may be involved in carrying one or more sequences of one or mom, instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the inflated signal and place the data on bus BS. Bus BS carries the data to main memory MM. from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT. network data link NDL, local network LAN and communication interface CI. One such downloaded application may provide all or pan of a method described herein, for example. The received code may be executed by processor PRO as it is received, and/or stored in storage device SD, or other non-volatile storage for later execution. In this manner, computer system CS may obtain application code in the form of a carrier wave.

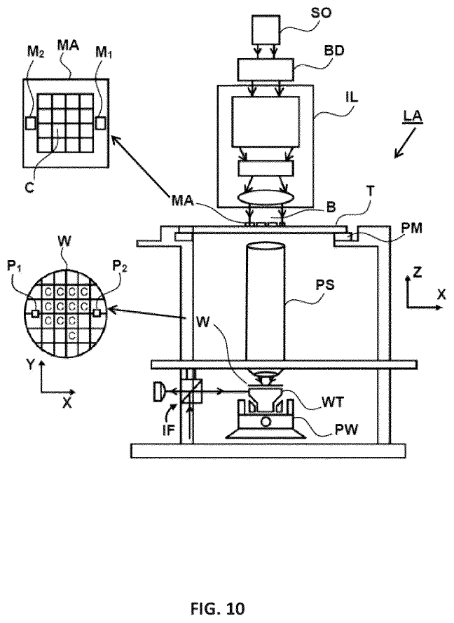

FIG. 10 is a schematic diagram of a lithographic projection apparatus, according to one or more embodiments. The lithographic projection apparatus can include an illumination system IL, a first object table MT, a second object table WT, and a projection system PS.

Illumination system IL can condition a beam B of radiation. In this particular case. the illumination system also comprises a radiation source SO.

First object table (e.g., patterning device table) MT can be provided with a patterning device holder to hold a patterning device MA (e.g., a reticle), and connected to a first positioner PM to accurately position the patterning device with respect to item PS.

Second object table (substrate table) WT can be provided with a substrate holder to hold a substrate W (e.g., a resist-coated silicon wafer), and connected to a second positioner PW to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted, the apparatus can be of a transmissive type (i.e., has a transmissive patterning device). However, in general, it may also be of a reflective type, for example (with a reflective patterning device). The apparatus may employ a different kind of patterning device to classic mask, examples include a programmable mirror array or LCD matrix.

The source SO (e.g., a mercury lamp or excimer laser, LPP (laser produced plasma) EUV source) produces a beam of radiation. This beam is fed into illumination system (illuminator) IL, either directly or after having traversed conditioning apparatuses, such as a beam expander, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 losing).

The bin B can subsequently intercept patterning device MA, which is held on a patterning device table MT. Having traversed patterning device MA, the beam B can pass through the lens, which focuses beam B onto target portion C of substrate W. With the aid of the second positioning apparatus (and interferometric measuring apparatus IF), the substrate table WT can be moved accurately, e.g., so as to position different target portions C in the path of beam B. Similarly, the first positioning apparatus can be used to accurately position patterning device MA with respect to the path of beam B, e.g., after mechanical retrieval of the patterning device MA from a patterning device library, or during a scan. In general movement of the object tables MT. WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fired.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam B.

In scan mode. essentially the same scenario applies, except that a given target portion C is not exposed in a single “flash.” Instead, patterning device table MT is movable in a given direction (the so-called “scan direction”, e.g., the y direction) with a speed v. so that projection beam B is caused to scan over a patterning device image concurrently. substrate table WT is simultaneously moved in the same or opposite direction at a speed V=Mv, in which M is the magnification of the lens (typically, M=¼ or ⅕). In this manner, a relatively large target portion C can be exposed. without having to compromise on resolution.

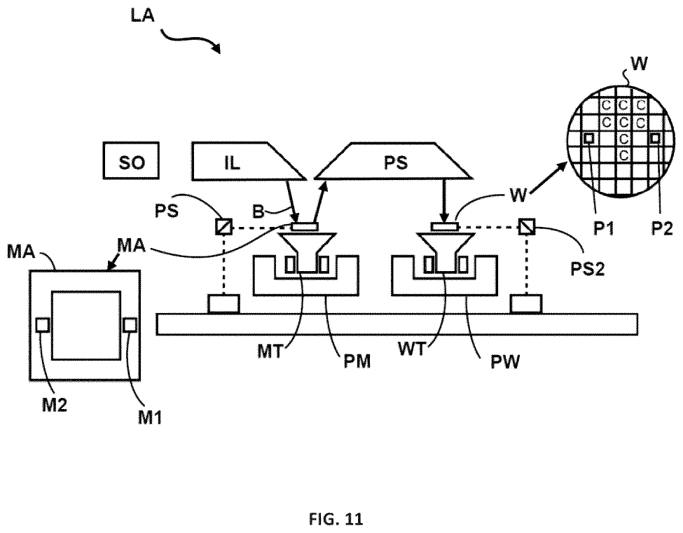

FIG. 11 is a schematic diagram of another lithographic projection apparatus (LPA), according to one or more embodiments. LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device.

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for exanol, a multi-stack of molybdenum and silicon. In one example, the multi-stack reflector has 41) laver pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TAN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to converting a material into a plasma state that has at least one element, e.g., xenon, lithium or tin, with one or more emission lines in the EUV range. in one such method, often termed laser produced plasma (“LPP”) the plasma can be produced by irradiating a fuel, such as a droplet, stream or cluster of material liming the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form pan of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least die outer and/or inner radial extent (commonly referred to as σ-outer and σ-inner, respectively)) of the intensity distribution in a pupil plane of the illuminator can be adjusted. In addition, the illuminator IL. may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor). the substrate table WT can be moved accurately. e.g. so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes. step mode, scan mode, and stationary mode.

In step mode, the support structure (e.g., patterning device table) MT and the substrate table WT are kept essentially stationary. while an entire pattern imparted to the radiation beam is projected onto a target portion C at one time (i.e., a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e., a single dynamic exposure). The velocity and direction of substrate table WT relative to the support structure (e.g., patterning device table) MT may be determined by the (de-) magnification and image reversal characteristics of the projection system PS.

In stationary mode, the support structure (e.g., patterning device table) MT is kept essentially stationary holding a programmable patterning device, and substrate table WT is moved or scanned while a pattern imported to the radiation beam is projected onto a target portion C. In this mode. generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

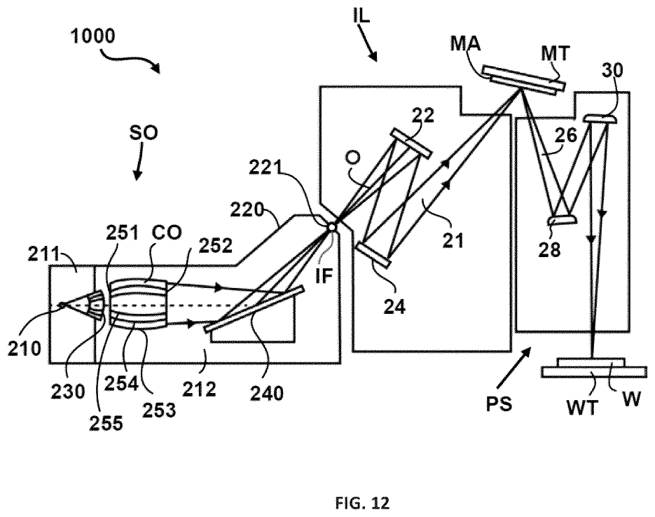

FIG. 12 is a detailed view of the lithographic projection apparatus, according to one or more embodiments. As shown. LPA can include the source collector module SO. the illumination system FL, and the projection system PS. The source collector module SO is configured such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to omit radiation in the EUV range of the electromagnetic spectrum. The hot plasma HP is created by, for example, an electrical discharge causing at least partially ionized plasma. Partial pressures of for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grating incidence collector. Radiation collector CO has an upstream radiation collector side US and a downstream radiation collector side DS. Radiation that traverses radiation collector CO can be reflected of a grating spectral filter SF to be focused in a virtual source point IF along the optical axis indicated by the dot-dashed line ‘O’. The virtual source point IF can be referred to as the intermediate focus, and the source collector module con be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror deuce PM arranged to provide a desired angular distribution of the radiation beam B, at the patterning device MA, as well as a desired uniformity of radiation amplitude at the patterning device MA. Upon reflection of the beam of radiation B at the patterning device MA. held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present. depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR just as an example of a collector (or collector mirror). The grazing incidence reflectors GR are disposed axially symmetric around the optical axis O and a collector optic CO of this type may be used in combination with a discharge produced plasma source, often called a DPP source.

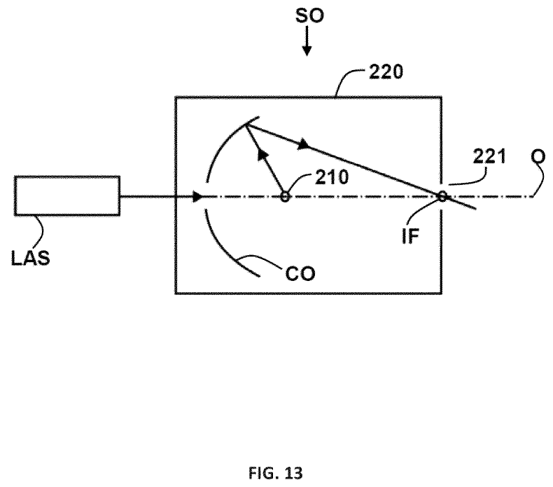

FIG. 13 is a detailed view of source collector module SO of lithographic projection apparatus LPA, according to one or more embodiments. Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultraviolet). DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or b % hitting a material (either solid or a plasma) with high energy electrons in order to produce photons within this range.

Embodiments of the present disclosure can be farther described by the following clauses.
1. A method for determining a source and mask configuration for a lithographs process. the method comprising:
obtaining a source configuration, a mask configuration, or a combination thereof;
calculating a probability distribution of edge placement error for a lithographic process based on the source configuration, the mask configuration, or the combination thereof and
adjusting the source configuration, the mask configuration, or the combination thereof based on the probability distribution.
2. The method of clause 1, wherein the edge placement error comprises a simulated edge placement error.
3. The method of clause 1, wherein the edge placement error is obtained from a model calibrated based on a measured edge placement error.
4. The method of clause 1, wherein the probability distribution corresponds to a stochastic probability distribution.
5. The method of clause 1, wherein the probability distribution is a simulated probability distribution.
6. The method of clause 1, wherein the probability distribution is calibrated based on a measured probability distribution.
7. The method of clause 1, further comprising determining a convolution of the probability distribution of edge placement error and at least an additional probability distribution and wherein adjusting the source configuration, the mask configuration, or the combination thereof based on the probability distribution comprises adjusting the source configuration, the mask configuration, or the combination thereof based on the convolution.
8. The method of clause 7, wherein the convolution is an asymmetrical distribution.
9. The method of clause 1, wherein the probability distribution of edge placement error is a Gaussian or a Poisson distribution.
10. The method of clause 1, wherein the probability distribution comprises a cumulative probability function.
11. The method of clause 1, further comprising calculating an offset function between the probability distribution and a reference probability distribution, and wherein the adjusting is based on the offset function.
12. The method of clause 11, wherein the reference probability distribution is a cumulative probability function.
13. The method of clause 1, wherein the reference probability distribution is a step or staircase function.
14. The method of clause 11, wherein the offset function between the probability distribution and the reference probability distribution is an Lp norm.
15. The method of clause 1. % herein the adjusting comprises adjusting the source configuration, the mask configuration, or the combination thereof until a difference between the probability distribution and a reference probability distribution is within a threshold range.
16. The method of clause 1, wherein the calculating comprises calculating a probability distribution of the edge placement error at multiple locations in a plane, and wherein the adjusting comprises adjusting the source configuration, the mask configuration, or the combination thereof based on the probability distribution in the multiple locations in the plane.
17. The method of clause 1. therein the calculating comprises calculating a probability distribution of the edge placement error in a plurality of planes, and wherein the adjusting comprises adjusting the source configuration, the mask configuration, or the combination thereof based on the probability distribution in the plurality of planes.
18. The method of clause 17, wherein the adjusting comprises adjusting the source configuration, the mask configuration, or the combination thereof based on a summation of the probability distribution in at least two of the plurality of planes.
19. The method of clause 1, wherein the calculating further comprises calculating one or more imaging performance metrics, and wherein the adjusting comprising adjusting the source configuration, the mask configuration, or the combination thereof based on the probability distribution of edge placement error and the one or more imaging performance metrics.
20. The method of clause 19, wherein the one or more imaging performance metrics comprise at least one of a critical dimension (CD), a critical dimension uniformity (CDU), a local critical dimension uniformity (LCDU), a line edge roughness (LER). a line width roughness (LWR), a resist contour characteristic, a maximum defect site, an exposure latitude, a pattern placement error, a mask error enhancement factor, a focus, a depth of focus (DOF), a DOF latitude, a critical dimension depth of focus, a process window, a process window latitude, a common process window, a common process window latitude, an image contrast, an image log slope (ILS), a normalized image log-slope (MILS), a usable process window above a specific NILS threshold (nDOF), mask error enhancement factor (MEEF), or a combination thereof.
21. The method of clause 1, wherein the adjusting comprises:
determining a multi-variable cost function for the lithographic process based on the probability distribution of edge placement error.
wherein the lithographic process comprises a lithographic process corresponding to the source configuration, the mask configuration, of the combination thereof; and
reconfiguring one or more characteristics of the lithographic process until a termination criterion is satisfied.
22. The method of clause 21, wherein the multi-variable cost function comprises a multi-variable cost function of a plurality of design variables that represent characteristics of the lithographic process and wherein the reconfiguring comprises reconfiguring one or more characteristics of the lithographic process by adjusting one or more of the plurality of design variables until the termination criterion is satisfied.
23. The method of clause 1, wherein the obtaining comprises obtaining the source configuration, the mask configuration, or the combination thereof from a source model, a mask model, or a combination thereof.
24. A method comprising:
determining, by a computer system, a multi-variable cost function of a plurality of design variables that represent characteristics of a lithographic process, wherein the multi-variable cost function is correlated with a probability distribution of edge placement,
wherein the probability distribution of edge placement accounts for stochasticity of edge placement; and
reconfiguring, by the computer system. one or more characteristics of the lithographic process by adjusting one or more of the plurality of design variables until a termination criteria is satisfied.
25. The method of clause 24, wherein the probability distribution of edge placement comprises a probability distribution of edge placement error.
26. The method of clause 24, wherein the probability distribution of edge placement is a simulated probability distribution of edge placement.
27. The method of clause 24, wherein the probability distribution of edge placement is informed by a measured probability distribution of edge placement.
28. The method of clause 24, wherein the probability distribution of edge placement comprises a contributions from a stochastic edge placement distribution and a deterministic edge placement distribution.
29. The method of clause 28, wherein the stochastic edge placement distribution comprises a convolution of two or more stochastic distributions.
30. The method of clause 29, wherein at least one of the stochastic distributions comprise at least one stochastic edge placement error distribution, photon shot noise distribution, stochastic dose error distribution, stochastic mask error distribution, metrology noise distribution, or a combination thereof.
31. The method of clause 24. further comprising calculating a distance between the probability distribution of edge placement and a reference distribution of edge placement, and wherein the reconfiguring is based on the distance.
32. The method of clause 24, wherein the multi-variable cost function is a function of the probability distribution of edge placement.
33. The method of clause 24, % herein the multi-variable cost function is a function of a variable that is a function of the probability distribution of edge placement.
34. The method of clause 24, wherein the probability distribution of edge placement is a function of a variable that effects the probability distribution of edge placement.
35. The method of clause 24, wherein the determining comprises.
determining. by the computer system, a first multi-variable cost function of a plurality of design variables that represent characteristics of the lithographic process, wherein the first multi-variable cost function is correlated with edge placement; and
reconfiguring, by the computer system, one or more characteristics of the lithographic process by adjusting one or more of the plurality of design variables until a first termination criteria is satisfied.
36. The method of clause 35, wherein the edge placement comprises an edge placement error.
37. The method of clause 35, wherein the determining further comprises:
determining, by the computer system, a second multi-variable cost function of a plurality of design variables that represent characteristics of the lithographic process, wherein the second multi-variable cost function is correlated with a stochastic probability distribution of edge placement; and
reconfiguring, by the computer system, one or more characteristics of the lithographic process by adjusting one or more of the plurality of design variables until a second termination criteria is satisfied.
38. The method of clause 37, wherein the stochastic probability distribution of edge placement comprises a stochastic probability distribution of edge placement error.
39. One of more non-transitory, machine-readable medium having instructions thereon, the instructions when executed by a processor being configured to perform the method of any one of clauses 1 to 38.
40. A system comprising:
a processor; and
one or more non-transitory, machine-readable medium having instructions thereon, the instructions when executed by the processor being configured to perform the method of any one of clause 1 to 38.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments. For example adding single or multiple assist features as described herein may comprise their own separate embodiments, or they may be included with one or more other embodiments described herein.

The descriptions above are intended to be illustrative, not limiting Thus, it will be apparent to one Wiled in the art that modifications may be made as described without departing from the scope of the claims set out below.

1. One of more non-transitory, machine-readable medium having instructions thereon or therein, the instructions, when executed by a processor system, configured to cause the processor system to at least:
obtain a source configuration, a mask configuration, or a combination thereof;
determine a probability distribution of edge placement error for a lithographic process based on the source configuration, the mask configuration, or the combination thereof; and
adjust, based on the probability distribution, the source configuration, the mask configuration, or the combination thereof.

2. The medium of claim 1, wherein the edge placement error comprises a simulated edge placement error, and wherein the probability distribution is a simulated probability distribution.

3. The medium of claim 1, wherein the probability distribution comprises a stochastic probability distribution.

4. The medium of claim 1, wherein the instructions are further configured to cause the processor system to determine a convolution of the probability distribution of edge placement error and at least an additional probability distribution, and wherein the instructions configured to cause the processor system to adjust the source configuration, the mask configuration, or the combination thereof are configured to cause the processor system to adjust, based on the convolution, the source configuration, the mask configuration, or the combination thereof.

5. The medium of claim 4, wherein the convolution comprises an asymmetrical distribution.

6. The medium of claim 1, wherein the probability distribution comprises a cumulative probability function, wherein the instructions are further configured to cause the processor system to determine an offset function between the probability distribution and a reference probability distribution, wherein the reference probability distribution is a cumulative probability function, and wherein instructions configured to cause the processor system to adjust the source configuration, the mask configuration, or the combination thereof are configured to cause the processor system to adjust, based on the offset function, the source configuration, the mask configuration, or the combination thereof.

7. The medium of claim 6, wherein the reference probability distribution is a step or staircase function, and wherein the offset function between the probability distribution and the reference probability distribution is an Lp norm, wherein the probability distribution of edge placement error is a Gaussian distribution or a Poisson distribution.

8. The medium of claim 1, wherein the instructions configured to cause the computer system to determine a probability distribution of edge placement error are configured to cause the computer system to determine a probability distribution of the edge placement error at multiple locations in a plane, and wherein the instructions configured to cause the processor system to adjust the source configuration, the mask configuration, or the combination thereof are configured to cause the processor system to adjust, based on the probability distribution in the multiple locations in the plane, the source configuration, the mask configuration, or the combination thereof.

9. The medium of claim 1, wherein the instructions configured to cause the computer system to determine a probability distribution of edge placement error are configured to cause the computer system to determine a probability distribution of the edge placement error in a plurality of planes, and wherein the instructions configured to cause the processor system to adjust the source configuration, the mask configuration, or the combination thereof are configured to cause the processor system to adjust, based on the probability distribution in the plurality of planes, the source configuration, the mask configuration, or the combination thereof.

10. The medium of claim 1, wherein the instructions configured to cause the computer system to determine a probability distribution of edge placement error are further configured to cause the computer system to determine one or more imaging performance metrics, and wherein the instructions configured to cause the processor system to adjust the source configuration, the mask configuration, or the combination thereof are configured to cause the processor system to adjust, based on the probability distribution of edge placement error and the one or more imaging performance metrics, the source configuration, the mask configuration, or the combination thereof.

11. The medium of claim 1, wherein the instructions configured to cause the processor system to adjust the source configuration, the mask configuration, or the combination thereof are configured to cause the processor system to:
determine a multi-variable cost function of a plurality of design variables that represent characteristics of the lithographic process, wherein the multi-variable cost function is correlated with a probability distribution of edge placement, and wherein the probability distribution of edge placement accounts for stochasticity of edge placement; and
reconfigure one or more characteristics of the lithographic process by adjustment of one or more of the plurality of design variables based on the multi-variable cost function.

12. The medium of claim 1, wherein the probability distribution of edge placement comprises a contribution from a stochastic edge placement distribution and from a deterministic edge placement distribution.

13. The medium of claim 1, wherein the distribution comprise a stochastic edge placement error distribution, a photon shot noise distribution, a stochastic dose error distribution, a stochastic mask error distribution, a metrology noise distribution, or a combination selected therefrom.

14. The medium of claim 11, wherein the multi-variable cost function is at least one selected from: a function of the probability distribution of edge placement; a function of a variable that is a function of the probability distribution of edge placement; or a and function of a variable that affects the probability distribution of edge placement.

15. The medium of claim 11, wherein the instructions configured to cause the processor system to determine the multi-variable cost function are configured to cause the processor system to:
determine a first multi-variable cost function of a plurality of design variables that represent characteristics of the lithographic process, wherein the first multi-variable cost function is correlated with edge placement; and
reconfigure one or more characteristics of the lithographic process by adjustment of one or more of the plurality of design variables until a first termination criteria is satisfied;
determine a second multi-variable cost function of a plurality of design variables that represent characteristics of the lithographic process, wherein the second multi-variable cost function is correlated with a stochastic probability distribution of edge placement; and
reconfigure one or more characteristics of the lithographic process by adjustment of one or more of the plurality of design variables until a second termination criteria is satisfied.

16. One of more non-transitory, machine-readable medium having instructions thereon or therein, the instructions, when executed by a processor system, configured to cause the processor system to at least:
determine a multi-variable cost function of a plurality of design variables that represent characteristics of a lithographic process, wherein the multi-variable cost function is correlated with a probability distribution of edge placement, wherein the probability distribution of edge placement accounts for stochasticity of edge placement; and
reconfigure one or more characteristics of the lithographic process by adjustment of one or more of the plurality of design variables until a termination criteria is satisfied.

17. The medium of claim 16, wherein the probability distribution of edge placement comprises a probability distribution of edge placement error, a simulated probability distribution of edge placement, a distribution informed by a measured probability distribution of edge placement, or contributions from a stochastic edge placement distribution and a deterministic edge placement distribution.

18. The medium of claim 16, wherein the instructions are further configured to cause the processor system to calculate a distance between the probability distribution of edge placement and a reference distribution of edge placement, and wherein the reconfiguration is based on the distance.

19. The medium of claim 16, wherein the multi-variable cost function comprises a function of the probability distribution of edge placement or a function of a variable that is a function of the probability distribution of edge placement.

20. The medium of claim 16, wherein the probability distribution of edge placement is a function of a variable that affects the probability distribution of edge placement.
